(19) United States
(12) Patent Application Publication
(10) Pub. No.: US 2026/0206230 A1
(43) Pub. Date: Jul. 16, 2026

(54) THREE-DIMENSIONAL MEMORY HAVING STRUCTURE INCLUDING SEPARATE WRITE WIRES AND READ WIRES

(71) Applicants: IUCF-HYU (Industry-University Cooperation Foundation Hanyang University), Seoul (KR); PeDiSem Co., Ltd., Seoul (KR)

(72) Inventors: Chang Eun Song, Seoul (KR); Yun Heub Song, Seoul (KR)

(73) Assignees: IUCF-HYU (Industry-University Cooperation Foundation Hanyang University), Seoul (KR); PeDiSem Co., Ltd., Seoul (KR)

(21) Appl. No.: 19/137,873

(22) PCT Filed: Oct. 24, 2023
(86) PCT No.: PCT/KR2023/016537

§ 371 Date: Jun. 11, 2025

(30) Foreign Application Priority Data
Dec. 12, 2022 (KR) 10-2022-0172785

(51) Int. Cl. H10B 51/30; G11C 11/22; H10B 51/10; H10B 51/20

(52) U.S. Cl. CPC H10B 51/30; G11C 11/223; G11C 11/2273; G11C 11/2275; H10B 51/10; H10B 51/20

(57) ABSTRACT

Disclosed is a three-dimensional memory having a structure including separate write wires and read wires. According to an embodiment, the three-dimensional memory may comprise: gate electrodes that are formed on a substrate to extend in the horizontal direction and are stacked and spaced apart from each other in the vertical direction; vertical channel structures that pass through the gate electrodes and extend in the vertical direction, wherein each of the vertical channel structures includes a data storage pattern, a vertical channel pattern, and a back gate; write wires for a write operation of the three-dimensional memory, each of which is arranged on top of each of the vertical channel structures and connected to the vertical channel patterns; and read wires for a read operation of the three-dimensional memory, each of which is arranged below each of the vertical channel structures and connected to the back gates.

### TECHNICAL FIELD

The following embodiments relate to a memory having a three-dimensional structure, a method for operating the same, and a method for manufacturing the same.

### BACKGROUND ART

In addition to the advantages of low cost and large capacity, the three-dimensional NAND memory has already proven advantages related to program operation, such as the advantage of being able to block the operation of the remaining strings adjacent to the selected string to be subjected to program operation through self-boosting, and the advantage of being capable of completely blocking leakage current during program operation.

However, the three-dimensional NAND memory has a disadvantage that a reduction in cell current is caused during a read operation, and thus a high-speed operation requiring a current of several μA or more is not possible.

Therefore, the following embodiments are intended to propose a three-dimensional memory having a structure that uses a program operation of a conventional three-dimensional NAND memory and simultaneously uses a high-speed read operation through direct voltage sensing based on two terminals.

### DETAILED DESCRIPTION OF THE INVENTION

### Problem to be Solved

In order to solve the technical problem of enabling a high-speed read operation through direct voltage sensing based on two-terminals, while having advantages related to a program operation of a conventional three-dimensional NAND memory, the present disclosure proposes a three-dimensional memory comprising write wires for a write operation including the program operation and read wires for a read operation, the write wires and the read wires being separately provided, and operation method thereof, and a manufacturing method.

However, the technical problems to be solved by the present invention are not limited to the above problems, and can be variously extended without departing from the technical spirit and scope of the present invention.

### Means for Solving the Problem

According to an embodiment, a three-dimensional memory may include gate electrodes that are formed on a substrate to extend in the horizontal direction and are stacked and spaced apart from each other in the vertical direction; vertical channel structures that pass through the gate electrodes and extend in the vertical direction, wherein each of the vertical channel structures includes a data storage pattern, a vertical channel pattern, and a back gate; write wires for a write operation of the three-dimensional memory, each of which is arranged on top of each of the vertical channel structures and connected to the vertical channel patterns; and read wires for a read operation of the three-dimensional memory, each of which is arranged below each of the vertical channel structures and connected to the back gates.

According to one aspect, the write wires and the read wires may be respectively arranged at positions symmetrical to each other within the three-dimensional memory.

According to another aspect, each of the vertical channel structures arranged in a same row or a same column among the vertical channel structures may be connected to a different one of the write wires, and simultaneously be connected to a different one of the read wires.

According to still other aspect, the three-dimensional memory may perform the write operation of writing a polarization state of the data storage pattern along a write path between each of the gate electrodes and each of the write wires.

According to still other aspect, the three-dimensional memory may perform the read operation of reading a polarization state of the data storage pattern along a read path between each of the gate electrodes and each of the read wires.

According to still other aspect, the three-dimensional memory may determine, through voltage sensing, whether the polarization state of the data storage pattern is changed by a voltage applied along the read path between each of the gate electrodes and each of the read wires, thereby reading the polarization state of the data storage pattern.

According to still other aspect, when it is determined through the voltage sensing that the polarization state of the data storage pattern is changed by the voltage applied along the read path between each of the gate electrodes and each of the read wires, the three-dimensional memory may further perform a recovery operation of recovering the polarization state of the data storage pattern after the read operation.

According to still other aspect, the three-dimensional memory may have a source free structure in which a source region is omitted below each of the vertical channel structures.

According to still other aspect, the three-dimensional memory may perform the write operation on the target memory cell to be subjected to the write operation pre-charged in advance, and simultaneously pre-charge any one of the remaining vertical channel structures other than a selected vertical channel structure including the target memory cell among the vertical channel structures.

According to still other aspect, each of the vertical channel structures may further include a back gate dielectric pattern interposed between the vertical channel pattern and the back gate.

According to still other aspect, the back gate dielectric pattern may pre-charge the vertical channel pattern in response to a pass voltage being applied through the back gate during the write operation.

According to still other aspect, the back gate dielectric pattern may function as a conductive state of a switching element in response to a ground voltage being applied through the back gate during the read operation, thereby focusing on reading the polarization state of the data storage pattern.

According to an embodiment, the gate electrodes are stacked and spaced apart in the vertical direction while being formed to extend in the horizontal direction on the substrate; vertical channel structures extending in the vertical direction through the gate electrodes, each of the vertical channel structures including a data storage pattern, a vertical channel pattern, and a back gate; A method of a write operation of a three-dimensional memory comprising: write wires for a write operation, the write wires being disposed on top of each of the vertical channel structures and connected to the vertical channel pattern; and read wires for a read operation, the read wires being arranged below each of the vertical channel structures and connected with the back gate, the method comprising: applying a voltage along a write path between each of the gate electrodes and each of the write wires; and writing a polarization state of the data storage pattern by the voltage applied along the write path.

According to an aspect, the writing may further include: performing the write operation on a target memory cell that is a target of the write operation that has been pre-charged in advance, and at the same time, pre-charging any one vertical channel structure among the vertical channel structures except a selected vertical channel structure including the target memory cell.

According to another aspect, a back gate dielectric pattern interposed between the vertical channel pattern and the back gate may pre-charge the vertical channel pattern in response to a pass voltage being applied through the back gate in the write operation method.

According to an embodiment, a method of a read operation of a three-dimensional memory including: gate electrodes that are formed on a substrate to extend in the horizontal direction and are stacked and spaced apart from each other in the vertical direction; vertical channel structures that pass through the gate electrodes and extend in the vertical direction, wherein each of the vertical channel structures includes a data storage pattern, a vertical channel pattern, and a back gate; write wires for a write operation, each of which is arranged on top of each of the vertical channel structures and connected to the vertical channel patterns; and read wires for a read operation, each of which is arranged below each of the vertical channel structures and connected to the back gates, may include: applying a voltage along the read path between each of the gate electrodes and each of the read wires; and reading a polarization state of the data storage pattern by determining, through voltage sensing, whether the polarization state of the data storage pattern is changed by the voltage applied along the read path.

According to an aspect, when it is determined through the voltage sensing that the polarization state of the data storage pattern is changed by the voltage applied along the read path, the method of a read operation of a three-dimensional memory may further include performing a recovery operation of recovering the polarization state of the data storage pattern after the reading.

According to another aspect, a back gate dielectric pattern interposed between the vertical channel pattern and the back gate may function as a conductive state of a switching element in response to a ground voltage being applied through the back gate in the method of a read operation, thereby focusing on reading the polarization state of the data storage pattern.

According to an embodiment, a method for manufacturing a three-dimensional memory may include: preparing a semiconductor structure including: gate electrodes that are formed on a substrate to extend in the horizontal direction and are stacked and spaced apart from each other in the vertical direction; and vertical channel structures that pass through the gate electrodes and extend in the vertical direction, wherein each of the vertical channel structures includes a data storage pattern, a vertical channel pattern, and a back gate; arranging read wires for a read operation of the three-dimensional memory below each of the vertical channel structures, and connecting the read wires to the back gate; and arranging write wires for a write operation of the three-dimensional memory on top of each of the vertical channel structures, and connecting the write wires to the vertical channel patterns.

According to one aspect, the arranging the write wires on top of each of the vertical channel structures, and connecting the write wires to the vertical channel patterns may include arranging the write wires at positions symmetrical to the read wires within the three-dimensional memory.

### Effects of the Invention

According to an embodiment of the present disclosure, it is possible to achieve a technical effect of enabling a high-speed read operation through direct voltage sensing based on two-terminals, while having advantages related to a program operation of a conventional three-dimensional NAND memory, by proposing a three-dimensional memory having a structure in which write wires for a write operation including the program operation and read wires for a read operation are separately included, and an operation method and a manufacturing method thereof.

However, the effects of the present invention are not limited to the above effects, and may be variously extended without departing from the technical spirit and scope of the present invention.

### BRIEF DESCRIPTION OF THE DRAWINGS

FIG. 1 is a simplified circuit diagram showing an array of three-dimensional memory according to an embodiment.

FIG. 2A is a plan view showing a structure of a three-dimensional memory according to an embodiment, and corresponds to a cross-section with reference to a top of vertical channel structures in which write wires are arranged.

FIG. 2B is a plan view showing a structure of a three-dimensional memory according to an embodiment, and corresponds to a cross-section with reference to a bottom of vertical channel structures in which read wires are arranged.

FIG. 3 is a cross-sectional view showing a structure of a three-dimensional memory according to an embodiment, and corresponds to a cross-section taken along line A-A′ in FIG. 2A and FIG. 2B.

FIG. 4 is a flowchart showing a method of a write operation of a three-dimensional memory according to an embodiment.

FIG. 5 is a diagram showing a structure of a three-dimensional memory to describe a method of a write operation of the three-dimensional memory according to an embodiment.

FIG. 6 is a diagram for describing a pre-charging operation performed in a method of a write operation of a three-dimensional memory according to an embodiment.

FIG. 7 is a flowchart showing a method of a read operation of a three-dimensional memory according to an embodiment.

FIG. 8 is a diagram showing a structure of a three-dimensional memory to describe a method of a read operation of the three-dimensional memory according to an embodiment.

FIGS. 9A to 9C are each a diagram for describing a method of a read operation of a three-dimensional memory according to an embodiment.

FIG. 10 is a diagram for describing a recovery operation performed after a method of a read operation of a three-dimensional memory is performed, according to an embodiment.

FIGS. 11A to 11B are each a diagram for describing a role of a gate dielectric pattern in method of a write operation and method of a read operation of a three-dimensional memory according to an embodiment.

FIG. 12 is a flowchart showing a method of manufacturing a three-dimensional memory according to an embodiment.

FIG. 13 is a perspective view schematically showing an electronic system including a three-dimensional memory according to one embodiment.

### BEST MODE FOR CARRYING OUT THE INVENTION

Hereinafter, embodiments of the present invention will be described in detail with reference to the accompanying drawings. However, the present invention is not limited or restricted by the embodiments. In addition, the same reference numerals shown in the respective drawings indicate the same members.

In addition, the terminologies used herein are terms used to appropriately represent a preferred embodiment of the present invention, which may vary depending on the intention of a viewer, an operator, or a practice in the field to which the present invention belongs. Accordingly, definitions of the terms should be made based on the context throughout this specification. For example, as used herein, the singular forms “a,” “an,” and “the” include plural referents unless the context clearly dictates otherwise. Also, “comprises” and/or “comprising,” as used herein, does not preclude the presence or addition of one or more other components, steps, operations, and/or elements. Further, although the terms first, second, and the like are used herein to describe various regions, directions, shapes, and the like, these regions, directions, and shapes should not be limited by these terms. These terms have only been used to distinguish a given region, direction or shape from another region, direction, or shape. Thus, a portion referred to as a first portion in one embodiment may be referred to as a second portion in another embodiment.

It should also be understood that the various embodiments of the present invention are different from each other, but need not be mutually exclusive. For example, the specific shapes, structures, and characteristics described herein may be implemented in other embodiments without departing from the spirit and scope of the invention in connection with one embodiment. It should also be understood that the position, arrangement, or configuration of individual components in each of the presented example categories may be modified without departing from the spirit and scope of the invention.

Hereinafter, a three-dimensional memory achieving a technical effect of enabling a high-speed read operation through direct voltage sensing based on two-terminals, while having advantages related to a program operation of a conventional three-dimensional NAND memory, an operation method thereof, and a manufacturing method thereof, will be described in detail with reference to the drawings.

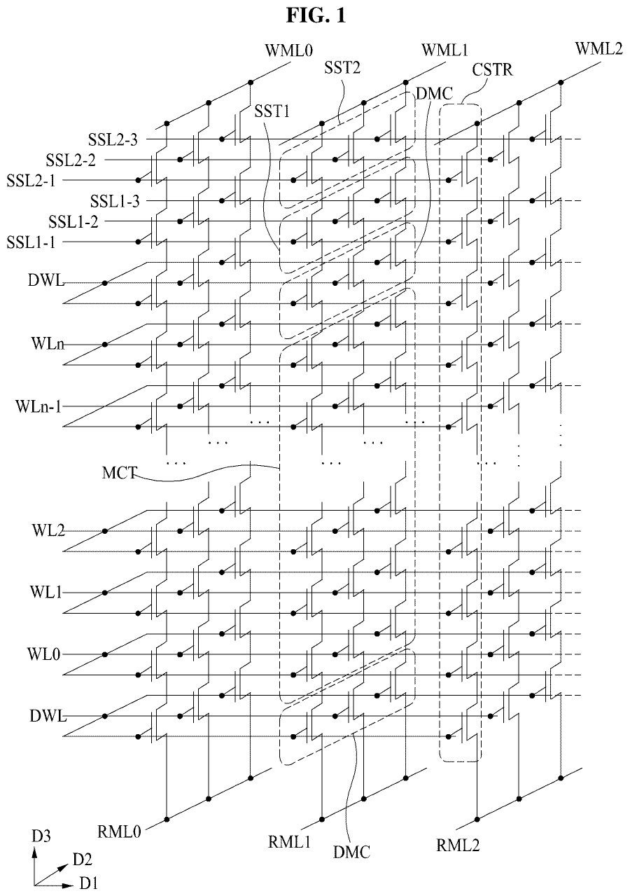

FIG. 1 is a simplified circuit diagram showing an array of three-dimensional memory according to an embodiment.

Referring to FIG. 1, an array of three-dimensional memory according to an embodiment may include a plurality of write wires (write metal lines; WML0, WML1, WML 2), a plurality of read wires (read metal lines; RML0, RML1, RML2), and a plurality of cell strings (CSTR) arranged between the write metal lines WML0, WML1, WML2 and the read metal lines RML0, RML1, RML2.

The write metal lines WML0, WML1, WML2 may be two-dimensionally arranged to be spaced apart from each other along the first direction D1 while extending in the second direction D2. Here, each of the first direction D1, the second direction D2, and the third direction D3 is orthogonal to each other and may form a rectangular coordinate system defined by the X, Y, Z axes.

Each of the write metal lines WML0, WML1, WML2 may be located at a top of the cell strings CSTR, and a plurality of cell strings CSTR may be connected in parallel to each of the write metal lines WML0, WML1, WML2.

The read metal lines RML0, RML1, RML2 may be two-dimensionally arranged to be spaced apart from each other along the first direction D1 while extending in the second direction D2.

Each of the read metal lines RML0, RML1, RML2 may be located at a bottom of the cell strings CSTR, and a plurality of cell strings CSTR may be connected in parallel to each of the read metal lines RML0, RML1, RML2.

The write metal lines WML0, WML1, WML2 and the read metal lines RML0, RML1, RML2 may be respectively arranged at positions symmetrical to each other within the three-dimensional memory. As an example, the position where the write metal lines WML0, WML1, WML2 are arranged on the two-dimensional plane (the plane formed by the first direction D1 and the second direction D2) with respect to the cell strings CSTR at the top of the cell strings CSTR may be symmetrical to the position where the read metal lines RML0, RML1, RML2 are arranged on the two-dimensional plan with respect to the cells strings CSTR, at the bottom of the cell Strings CSTR, as shown in the figure.

The cell strings CSTR may be arranged to be connected to each of the write metal lines WML0, WML1, WML2 and the read metal lines RML0, RML1, RML2 arranged along the second direction D2 while extending in the third direction D3. According to an embodiment, each of the cell strings CSTR is connected to the write metal lines WML0, WML1, WML2 and may be composed of first and second string selection transistors SST1, SST2 connected in series, and memory cell transistors MCTs connected in series while being arranged between the first and second string selecting transistors SST1, SST2 and the read metal lines RML0, RML1, RML2. In addition, each of the memory cell transistors MCTs may include a data storage element.

As an example, each the cell strings CSTR may include first and second string selection transistors SST1, SST2 connected in series, and the first and second string selecting transistors SST1, SST2 may be connected to one of the write metal lines WML0, WML1, WML2. However, without being limited or restricted thereto, each the cell strings CSTR may also include one string selection transistor.

One cell string CSTR may be composed of a plurality of memory cell transistors MCTs having different distances from the write metal lines WML0, WML1, WML2 and the read metal lines RML0, RML1, RML2. That is, the memory cell transistors MCTs may be connected in series while being arranged along the third direction D3 between the first string selection transistor SST1 and each of the read metal lines RML0, RML1, RML2. The highest one or the lowest one of the memory cell transistors MCT in each of the cell strings CSTR may be used as the dummy cell transistor DMC.

According to an embodiment, the first string selection transistor SST1 may be controlled by first string selection lines SSL1-1, SSL1-2, SSL1-3, and the second string selection transistor SST2 may be controlled by the second string selection lines SSL2-1, SSL2-2, SSL2-3. The memory cell transistors MCTs may be controlled by a plurality of word lines WL0-WLn, respectively, and the dummy cell transistors DMC may be controlled by the dummy word line DWL, respectively.

The gate electrodes of the memory cell transistors MCTs, which are provided at substantially the same distance from the write metal lines WML0, WML1, WML2 or the read metal lines RML0, RML1, RML2, may be commonly connected to one of the word lines WL0-WLn, DWL to be in an equipotential state. However, the present invention is not limited or restricted thereto, and even when the gate electrodes of memory cell transistors MCTs are provided at substantially the same level from the write metal lines WML0, WML1, WML2 or the read metal lines RML0, RML1, RML2, the gate electrodes provided in different rows or columns may still be controlled independently.

The first string selection lines SSL1-1, SSL1-2, SSL1-3 and the second string selection lines SSL2-1, SSL2-2, SSL2-3 extend along the first direction D1, may be spaced apart from each other in the second direction D2, and may be two-dimensionally arranged. The first string selection lines SSL1-1, SSL1-2, SSL1-3 and the second string selection lines SSL2-1, SSL2-2, SSL2-3 provided at substantially the same level from the write metal lines WML0, WML1, WML2 or the read metal lines RML0, RML1, RML2 may be electrically separated from each other.

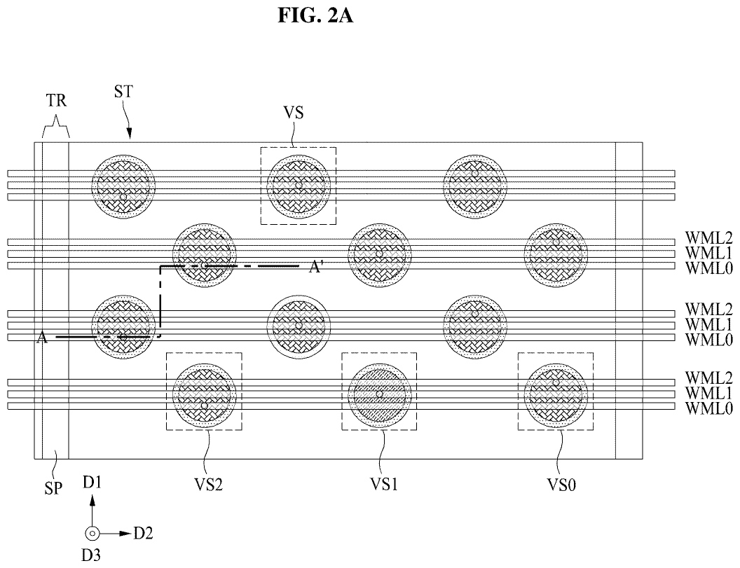

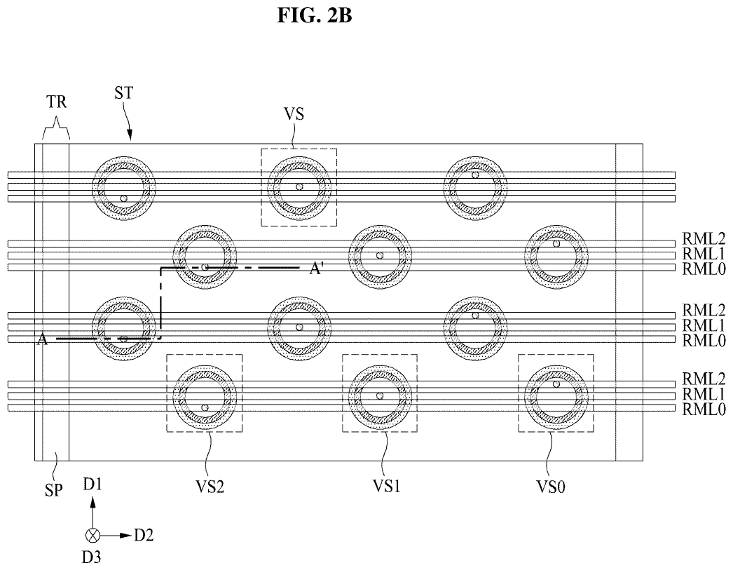

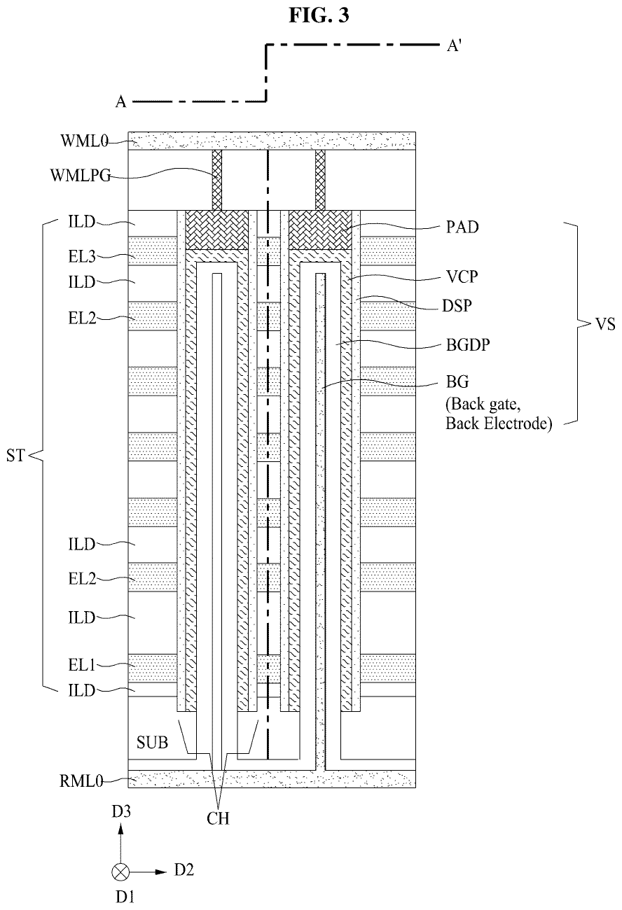

FIG. 2A is a plan view showing a structure of a three-dimensional memory according to an embodiment, and corresponds to a cross-section with reference to a top of vertical channel structures in which write wires are arranged, FIG. 2B is a plan view showing a structure of a three-dimensional memory according to an embodiment, and corresponds to a cross-section with reference to a bottom of vertical channel structures in which read wires are arranged, and FIG. 3 is a cross-sectional view showing a structure of a three-dimensional memory according to an embodiment, and corresponds to a cross-section taken along line A-A′ in FIG. 2A and FIG. 2B. Referring to FIGS. 2A, 2B, and 3, the substrate SUB may be a semiconductor substrate such as a silicon substrate, a silicon-germanium substrate, a germanium substrate, or a single-crystal epitaxial layer grown on a monocrystalline silicon substrate. The substrate SUB may be doped with a first conductivity type impurity (e.g., a P type impurity).

Stacked structures ST may be arranged on the substrate SUB. The stacked structures ST may be two-dimensionally disposed along the second direction D2 while extending in the first direction D1. Further, the stacked structures ST may be spaced apart from each other in the second direction D2.

Each of the stacked structures ST may include gate electrodes EL1, EL2, EL3 and interlayer insulating films ILD alternately stacked in a vertical direction (e.g., the third direction D3) perpendicular to the top surface of the substrate SUB. The stacked structures ST may have a substantially planar top surface. That is, the top surfaces of the stacked structures ST may be parallel to the top surface of the substrate SUB. Hereinafter, the vertical direction means a third direction D3 or a reverse direction of the third direction D3.

Referring back to FIG. 1, each the gate electrodes EL1, EL2, EL3 may be one of word lines WL0-WLn, DWL, first string selection lines SSL1-1, SSL1-2, SSL1-3, and second string selection lines SSL2-1, SSL2-2, SSL2-3, which are sequentially stacked on the substrate SUB.

Each of the gate electrodes EL1, EL2, EL3 may have substantially the same thickness in the third direction D3 while extending in the first direction D1. Hereinafter, the thickness means the thickness in the third direction D3. Each of the gate electrodes EL1, EL2, EL3 may be formed of a conductive material. For example, each of the gate electrodes EL1, EL2, EL3 may include at least one selected from a doped semiconductor (ex, doped silicon, or the like), a metal (ex, W (tungsten), Cu (copper), Al (aluminum), Ti (titanium), Ta (tantalum), Mo (molybdenum), Ru (ruthenium), Au (gold), or the like), or a conductive metal nitride (ex, titanium nitride, tantalum nitride, or the like). Each of the gate electrodes EL1, EL2, EL3 may include at least one of all metal materials that may be formed of ALD in addition to the described metal materials.

More specifically, the gate electrodes EL1, EL2, EL3 may include a lowermost first gate electrode EL1, an uppermost third gate electrode EL3, and a plurality of second gate electrodes EL2 between the first gate electrodes EL1 and the third gate electrodes EL3. Although the first gate electrode EL1 and the third gate electrode EL3 are illustrated and described in the singular form, respectively, this is illustrative and not limited thereto, and, if necessary, the first gate electrode EL1 and the third gate electrode EL3 may be provided in the plural form. The first gate electrode EL1 may correspond to the dummy word line DWL showed in FIG. 1. The second gate electrode EL2 may correspond to any one of the word lines WL0-WLn showed in FIG. 1. The third gate electrode EL3 may correspond to any one of the first string selection lines SSL1-1, SSL1-2, SSL1-3 showed in FIG. 1 or any one of the second string selection lines SSG2-1, SSL2-2, SSG2-3.

Although not shown, the end of each of the stacked structures ST may have a stepwise structure along the first direction D1. More specifically, the length of the gate electrodes EL1, EL2, EL3 of the stacked structures ST in the first direction D1 may decrease as they become larger from the substrate SUB. The length of the third gate electrode EL3 in the first direction D1 may be the smallest, and the distance between the substrate SUB and the third direction D3 may be the largest. The length of the first gate electrode EL1 in the first direction D1 may be the largest, and the distance between the substrate SUB and the third direction D3 may be the smallest. With the stepwise structure, each of the stacked structures ST may decrease in thickness as it moves away from an outer-most one of the vertical channel structures VS described later, and sidewalls of the gate electrodes EL1, EL2, EL3 may be spaced apart at regular intervals along the first direction D1 from a planar perspective.

Each of the interlayer insulating films ILD may have a different thickness. As an example, the lowermost one and the uppermost one of the interlayer insulating films ILD may have a smaller thickness than the other interlayer insulating films IL. However, this is illustrative and not limited thereto, and the thickness of each of the interlayer insulating films ILDs may have different thicknesses or may all be set to be the same according to the characteristics of the semiconductor device. The interlayer insulating films ILD may be formed of an insulating material for insulation between the gate electrodes EL1, EL2, EL3. In one example, the interlayer insulating films ILD may be formed of silicon oxide.

A plurality of channel holes CH passing through portions of the stacked structures ST and the substrate SUB may be provided. The vertical channel structures VS may be provided within the channel holes CH. The vertical channel structures VS are a plurality of cell strings CSTR showed in FIG. 1, and may extend in the third direction D3 while being connected to the substrate SUB. The connection of the vertical channel structures VS to the substrate SUB may be achieved by a portion of each of the vertical channel structures VS having a bottom surface in contact with the top surface of the substrate SUB, however, the present invention is not limited or restricted thereto, and the connection may alternatively be achieved by embedding them within the substrate SUB. When a portion of each of the vertical channel structures VS is embedded within the substrate SUB, the bottom surface of the vertical channel structure VS may be located at a lower level than the top surface of the substrate SUB.

A plurality of columns of vertical channel structures VS may be provided that pass through any one of the stacked structures ST. For example, as shown in FIGS. 2A-2B, columns of three vertical channel structures VS may pass through one of the stacked structures ST. However, without being limited or restricted thereto, columns of four or more vertical channel structures VS may pass through one of the stacked structures ST, or columns of one or more and two or less vertical channel structures (VS) may pass through the one of the stacked structure ST. In an adjacent pair of columns, the vertical channel structures VS corresponding to one column may be shifted in the first direction D1 from the vertical channel structure VS corresponding to the other column adjacent thereto. From a planar perspective, the vertical channel structures VS may be arranged in a zigzag shape along the first direction D1. However, without being limited or restricted thereto, the vertical channel structures VS may also form an arrangement arranged side by side in rows and columns.

Each of the vertical channel structures VS may be formed to extend from the substrate SUB in the third direction D3. Although each of the vertical channel structures VS is showed as having a columnar shape in which the widths of the top and the bottom are the same in the figure, it may have a shape in the widths in the first direction D1 and the second direction D2 may be increased toward the third direction D3 without being limited or restricted thereto. The top surface of each of the vertical channel structures VS may have a circular shape, an elliptical shape, a square shape, or a bar shape.

Such vertical channel structures VS may correspond to channels of the first and second string select transistors SST1, SST2 and memory cell transistors MCT shown in FIG. 1.

Each of the vertical channel structures VS may include a data storage pattern DSP, a vertical channel pattern VCP, a back gate BG, and a conductive pad PAD. In each of the vertical channel structures VS, the data storage pattern DSP and the vertical channel pattern VCP may have an open-bottom pipe shape or a macaroni shape, and the back gate BG may have a shape that fills the inner space of the vertical channel pattern VCP with at least a portion surrounded by the vertical channel pattern VCP. In addition, as showed in the figure, a back gate dielectric pattern BGDP may be interposed between the vertical channel pattern VCP and the back gate BG.

The data storage pattern DSP may cover the inner wall of each of the channel holes CH, surround the outer wall of the vertical channel pattern VCP on the inner side, and contact sidewalls of the gate electrodes EL1, EL2, EL3 on the outer side. Accordingly, regions corresponding to the second gate electrodes EL2 in the data storage pattern DSP may constitute memory cells in which a memory operation (a write operation including a program operation and an erase operation, and a read operation) is performed by a voltage applied through the second gate electrodes EL2, together with regions corresponding to the second gate electrodes EL2 in the vertical channel pattern VCP. The memory cells correspond to the memory cell transistors MCTs shown in FIG. 1. To this end, the data storage pattern DSP may be a data storage element representing a data value in a polarization state of charges by a voltage applied through the second gate electrodes EL2.

For example, the data storage pattern DSP may be formed of a ferroelectric material to exhibit a binary data value or a multi-valued data value in the polarization state of the charges. The ferroelectric material may include at least one of HfOₓ, PZT(Pb(Zr, Ti)O₃), PTO(PbTiO₃), SBT(SrBi₂Ti₂O₃), BLT(Bi(La, Ti)O₃), PLZT(Pb(La, Zr)TiO₃), BST(Bi(Sr, Ti)O₃), barium titanate (BaTiO₃), P(VDF-TrFE), PVDF, AlOₓ, ZnOₓ, TiOₓ, TaOₓ or InOₓ, doped with at least one material of the HfOₓ, Al, Zr, or Si having an orthorhombic crystal structure.

Although the data storage pattern DSP is shown to extend in the vertical direction (e.g., the third direction D3) in the figures, the data storage pattern may have a plurality of segmented structures that are arranged to be spaced apart only in regions corresponding to the second gate electrodes EL2 on the outer wall of the vertical channel pattern VCP and on the inner wall of each of the channel holes CH, without being limited or restricted thereto.

The vertical channel pattern VCP may cover an inner wall of the data storage pattern DSP and may extend in a vertical direction (e.g., the third direction D3). The vertical channel pattern VCP may be provided between the data storage pattern DSP and the back gate BG (or between the data storage patterns DSP and the back gate dielectric patterns BGDP when the back gate dielectric pattern BGDP is included), and may constitute memory cells together with regions corresponding to the second gate electrodes EL2 in the data storage pattern DSP.

The top surface of the vertical channel pattern VCP may be located at a higher level than the top surface of the uppermost one of the second gate electrodes EL2. More specifically, the top surface of the vertical channel pattern VCP may be located between the top surface and the bottom surface of the third gate electrode EL3.

The vertical channel pattern VCP is a component that transfers charge or holes to the data storage pattern DSP and may be formed of monocrystalline silicon or polysilicon to form or boost channels by an applied voltage. However, without being limited or restricted thereto, the vertical channel pattern VCP may be formed of an oxide semiconductor material capable of blocking, suppressing, or minimizing leakage current. For example, the vertical channel pattern VCP may be formed of an oxide semiconductor material including at least one of In, Zn, or Ga having excellent leakage current characteristics, a Group 4 semiconductor material, or the like. The vertical channel pattern VCP may be formed of a ZnOx-based material including, for example, AZO, ZTO, IZO, ITO, IGZO, Ag-ZnO, or the like. Accordingly, the vertical channel pattern VCP may block, suppress, or minimize leakage current to the gate electrodes EL1, EL2, EL3 or the substrate SUB, and may improve transistor characteristics (e.g., threshold voltage distribution and speed of program/read operation) of at least one of the gate electrodes EL1, EL2, EL3, and consequently enhance electrical characteristics of the three-dimensional memory.

The top of the vertical channel pattern VCP may be connected to the write metal lines WML0, WML1, WML2 for the write operation. The write metal lines WML0, WML1, WML2 may be electrically connected to the vertical channel pattern VCP of each of the vertical channel structures VS by being two-dimensionally arranged to be spaced apart from each other along the first direction D1 while being formed to extend in the second direction D2 and being arranged on top of each of the vertical channel structures VS. Each of the write metal lines WML0, WML1, WML2 may be electrically connected to the vertical channel pattern VCP through a write metal line contact plug WMLPG.

Accordingly, a write path from each of the second gate electrodes EL2 toward each of the write metal lines WML0, WML1, WML2 may be formed by the voltage applied to each of the second gate electrodes EL2 and the voltage applied to each of the write metal lines WML0, WML1, WML2 during a write operation of the three-dimensional memory.

Each of the write metal lines WML0, WML1, WML2 may be formed of a conductive material including at least one selected from a doped semiconductor (ex, doped silicon, or the like), a metal (ex, W (tungsten), Cu (copper), Al (aluminum), Ti (titanium), Ta (tantalum), Mo (molybdenum), Ru (ruthenium), Au (gold), or the like), or a conductive metal nitride (ex, titanium nitride, tantalum nitride, or the like) to apply a voltage.

The back gate BG may be formed to come into contact with at least a portion surrounded by the vertical channel pattern VCP and apply a voltage to the vertical channel pattern VCP for memory operation, and may be referred to as a rear electrode, a back electrode, or the like. To this end, the back gate BG may be formed of a conductive material including at least one selected from a doped semiconductor (ex, doped silicon, or the like), a metal (ex, W (tungsten), Cu (copper), Al (aluminum), Ti (titanium), Ta (tantalum), Mo (molybdenum), Ru (ruthenium), Au (gold), or the like), or a conductive metal nitride (ex, titanium nitride, tantalum nitride, or the like). The back gate BG may include at least one of all metal materials that may be formed of ALD in addition to the described metal materials.

In this case, the back gate BG may be formed to extend along the third direction D3 from a level corresponding to the first gate electrode EL1 to a level corresponding to a second gate electrode EL2 within the vertical channel pattern VCP. That is, the top surface of the back gate BG may be positioned at a higher level than the top surface of an uppermost one of the second gate electrodes EL2. However, without being limited or restricted thereto, the back gate BG may also be formed to extend along the third direction D3 to a level corresponding to the third gate electrode EL3 within the vertical channel pattern VCP.

The back gate BG of such a structure may be used for application of a voltage to set, change, and maintain the polarization state of the charges of the ferroelectric-based data storage pattern DSP in a memory operation (e.g., a write operation and a read operation) of a three-dimensional memory. Accordingly, a voltage applied to the back gate BG through the read metal lines RML0, RML1, RML2 may cause a memory operation of the three-dimensional memory together with a voltage applied to word lines WL0-WLn and a voltage applied through the write metal lines WML0, WML1, WML2 connected to the vertical channel structures VS, respectively. A detailed description thereof will be described below.

The bottom of the back gate BG may be connected to the read metal lines RML0, RML1, RML2 for a read operation. The read metal lines RML0, RML1, RML2 may be electrically connected to the back gate BG of each of the vertical channel structures VS by being two-dimensionally arranged to be spaced apart from each other along the first direction D1 while being formed to extend in the second direction D2 and being arranged below each of the vertical channel structures VS. Each of the read metal lines RML0, RML1, RML2 may be directly electrically connected to the back gate BG, without being limited or restricted thereto, and may also be electrically connected to the back gate BG through the read metal line contact plug RMLPG.

Therefore, the read path from each of the second gate electrodes EL2 toward each of the read metal lines RML0, RML1, RML2 may be formed by a voltage applied to each of the second gate electrodes EL2 and a voltage applied to each of the read metal lines RML0, RML1, RML2 during a read operation of the three-dimensional memory.

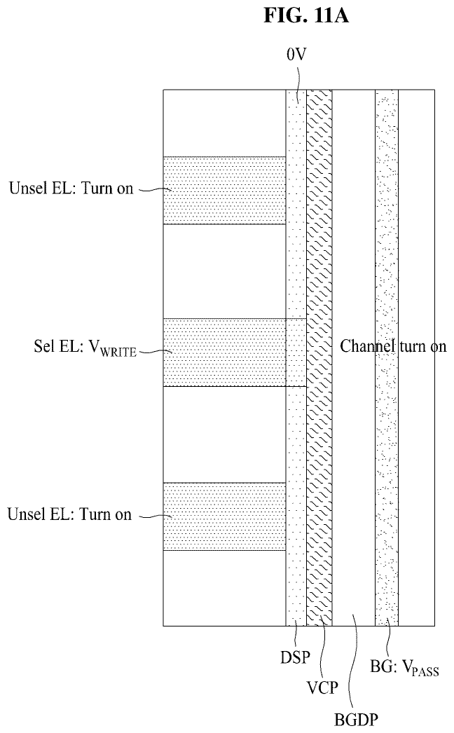

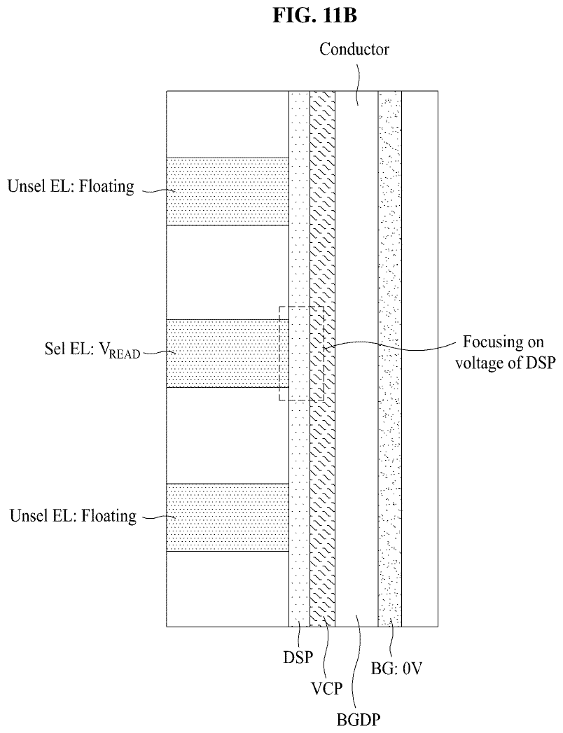

The back gate dielectric pattern BGDP is arranged between the back gate BG and the vertical channel pattern VCP, and may be used in different roles in the write operation method and the read operation method. A detailed description thereof will be described below with reference to FIGS. 11A to 11B. However, the back gate dielectric pattern BGDP may be omitted according to an implementation example.

Although it has been described above that the back gate BG is formed in the inner hole of the vertical channel pattern VCP and is formed to be tightly surrounded by the vertical channel pattern VCP, it is not limited or restricted thereto, and may be formed in a structure in which at least a portion is surrounded by the vertical channels pattern VCP. For example, a structure in which the back gate BG and the back gate dielectric pattern BGDP are included in at least a portion of the vertical channel pattern VCP or a structure passing through the vertical channel pattern VCP may be implemented.

The described write metal lines WML0, WML1, WML2 and read metal lines RML0, RML1, RML2 may be respectively arranged at positions symmetrical to each other within the three-dimensional memory. For example, a position where the write metal lines WML0, WML1, WML2 are arranged at the top of each of the vertical channel structures VS may be symmetrical to a position where the read metal lines RML0, RML1, RML2 are arranged below each of the vertical channel structures VS, as shown in FIGS. 2A and 2B. As a more specific example, the first write metal line WML0 may be arranged at a position that is vertically symmetrical to the first read metal line RML0, and the second write metal line WML1 may be arranged at the position that is vertically symmetrical to the second read metal line RML1.

Referring again to FIGS. 2A and 2B, each of the vertical channel structures VS arranged in the same row of the vertical channel structure VS may be connected to a different one of the write metal lines WML0, WML1, WML2 while being connected to a different read wire among the read metal lines RML0, RML1, RML2. That is, each of the vertical channel structures VS arranged in the same row may be connected to different write wires through the write metal line contact plugs WMLPG arranged in an offset manner, and may simultaneously be connected to the different read wires by the back gates BG arranged in an offset manner. As an example, if the first vertical channel structure VS0, the second vertical channel structure VS1, and the third vertical channel structure VC2 are located in the same row, the first vertical channel structures VS0 may be connected to the first write metal line WML0 through the first write metal line contact plug WMLPG0, the second vertical channel structure VS1 may be connected with the second write metal line WML1 through the second write metal line contact plugs WMLPG1, and the third vertical channel structure VS2 may be connected with a third write metal line WML2 through a third write metal line contact plug WMLPG2.

The conductive pad PAD may be provided on an top surface of the vertical channel pattern VCP. The conductive pad PAD may be connected to an upper portion of the vertical channel pattern VCP. A sidewall of the conductive pad PAD may be surrounded by the data storage pattern DSP. The top surface of the conductive pad PAD may be substantially coplanar with the top surface of each of the stacked structures ST (i.e., the top surface of an uppermost portion of the interlayer insulating films ILD). The bottom surface of the conductive pad PAD may be located at a lower level than the top surface of the third gate electrode EL3. More specifically, a bottom surface of the conductive pad PAD may be positioned between a top surface and a bottom surface of the third gate electrode EL3. That is, at least a portion of the conductive pad PAD may overlap the third gate electrode EL3 in the horizontal direction.

The conductive pad PAD may be formed of an impurity-doped semiconductor or a conductive material. For example, the conductive pad PAD may be formed of a semiconductor material doped with an impurity different from that of the substrate SUB (more precisely, an impurity of a second conductivity type (e.g., N type) different from that of a first conductivity type (e, g., P type)).

The conductive pad PAD may reduce contact resistance between the write metal lines WML0, WML1, WML2 and the vertical channel pattern VCP.

As described, the three-dimensional memory may have a source free structure in which a source region is omitted below each of the vertical channel structures VS.

A separation trench TR extending in the first direction D1 may be provided between the stacked structures ST adjacent to each other. Insulating spacers SP are formed in the separation trench TR, whereby the stacked structures ST adjacent to each other may be separated from each other. For example, the insulating spacers SP may be formed of silicon oxide, silicon nitride, silicon oxynitride, or a low-k material having a low dielectric constant.

A capping insulating film CAP may be provided on the stacked structures ST, the vertical channel structures VS, and the insulating spacers SP. The capping insulating film CAP may cover a top surface of an uppermost portion of the interlayer insulating films ILD, a top surface of the conductive pad PAD, and a top surface of a common source plug CSP. The capping insulating film CAP may be formed of an insulating material different from the interlayer insulating films ILD. The write metal line contact plug WMLPG electrically connected to the conductive pad PAD and the write metal lines WML0, WML1, WML2 may be provided inside the capping insulating film CAP. The bit line contact plug BLPG may have a shape in which the width in the first direction D1 and the width in the second direction D2 increases toward the third direction D3.

The three-dimensional memory according to an embodiment is not limited to or restricted to the described structure, and may be implemented in various structures on the premise that the three-dimensional memory includes the vertical channel pattern VCP, the ferroelectric-based data storage pattern DSP, the back gate BG, the gate electrodes EL1, EL2, EL3, the write metal lines WML0, WML1, WML2, and the read metal lines RML0, RML1, RML2, according to an implementation example.

An operation method and a manufacturing method for a three-dimensional memory having a structure including a write wire and a read wire as described above will be described below.

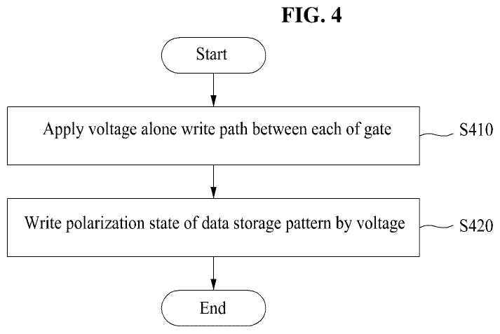

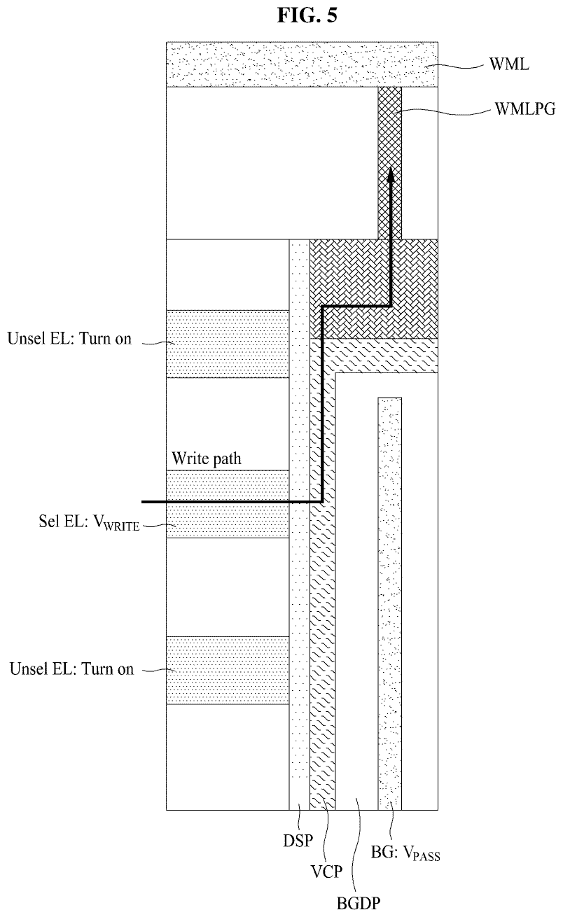

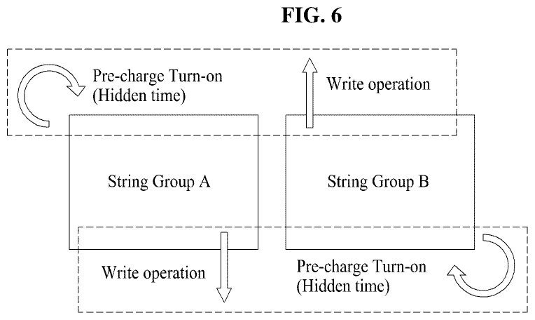

FIG. 4 is a flowchart showing a method of a write operation of a three-dimensional memory according to an embodiment, FIG. 5 is a diagram showing a structure of a three-dimensional memory to describe a method of a write operation of the three-dimensional memory according to an embodiment, and FIG. 6 is a diagram for describing a pre-charging operation performed in a method of a write operation of a three-dimensional memory according to an embodiment.

It is assumed that the write operation method described below is performed by a three-dimensional memory having the structure described above with reference to FIGS. 1 to 3. Referring to FIG. 4, in step S410, the three-dimensional memory may apply a voltage along the write path (the write path from each of the gate electrodes EL1, EL2, EL3 toward each of the write metal lines WML0, WML1, WML2) between each of the gate electrodes EL1, EL2, EL3, and each of the write metal lines WML0, WML1, WML2.

For example, as shown in FIG. 5, the three-dimensional memory applies a write voltage VWRITE of a positive value or a negative value to the selected gate electrode Sel EL corresponding to the target memory cell to be subjected to the write operation among the gate electrodes EL1, EL2, EL3, and turns on the remaining gate electrodes Unsel EL while applying a ground voltage to the write metal line WML (applying a pass voltage VPASS to the back gate BG of the selected vertical channel structure Sel VS including the target memory cell subject to the write operation, among the vertical channel structures VS, and at the same time, floating the remaining gate electrodes Unsel EL to turn on the remaining gate electrodes Unsel EL. When there is no back gate BG, the pass voltage VPASS is applied to each of the remaining gate electrodes Unsel EL to turn on, whereby a voltage can be applied along a write path (a write path including the selected gate electrode Sel EL, the data storage pattern DSP, the vertical channel pattern VCP in which the channel is formed, and the write wires) from the selected gate electrode Cel EL toward the write wires.

Accordingly, in step S420, the three-dimensional memory may write the polarization state of the data storage pattern DSP by the voltage applied along the write path. Hereinafter, writing the polarization state of the data storage pattern DSP means changing and maintaining the polarization state of a data storage pattern DSP to a polarization state corresponding to “1” data or a polarization state corresponding to “0” data.

In this case, the three-dimensional memory may perform a write operation on a target memory cell to be subjected to the write operation, and at the same time, pre-charging any one vertical channel structure Unsel VS other than the selected vertical channel structure Sel VS including the target memory cell among the vertical channel structures VS. Accordingly, the next write operation may be performed on the pre-charged vertical channel structure VS. In addition, it is assumed that the target memory cell wrote in step S420 is precharged in advance.

Here, pre-charging the vertical channel structure VS means applying the pass voltage VPASS to the vertical channel pattern VCP included in the vertical channel structure VS to turn on the vertical channel pattern, and pre-charging a vertical channel pattern VPC means applying the pass pressure VPASS to a vertical channel pattern VCP to turn on the vertical channel pattern.

That is, as shown in FIG. 6, the three-dimensional memory performs a pre-charging operation on the vertical channel structures VS included in the group B when performing a write operation on the vertical channels VS included in a group A, and then performs a pre-charge operation on the vertical channels structures VS included into the group A when performing a write operations on the vertical channel structure VS included into a group B, thereby achieving a technical effect of not performing the pre-charge operation separately from the write operation over time.

Such a write operation method corresponds to a memory operation method of FeFET.

When the back gate dielectric pattern BGDP is interposed between the vertical channel pattern VCP and the back gate BG in the three-dimensional memory, the back gate dielectric patterns BGDP may precharge the vertical channel patterns VCP in response to the pass voltage VPASS being applied to the back gates BG in steps S410 to S420, so that a channel is formed in the vertical channel patterns BCP and a polarization state is wrote in the data storage patterns DSP.

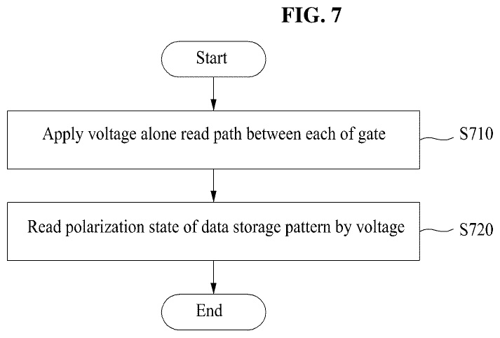

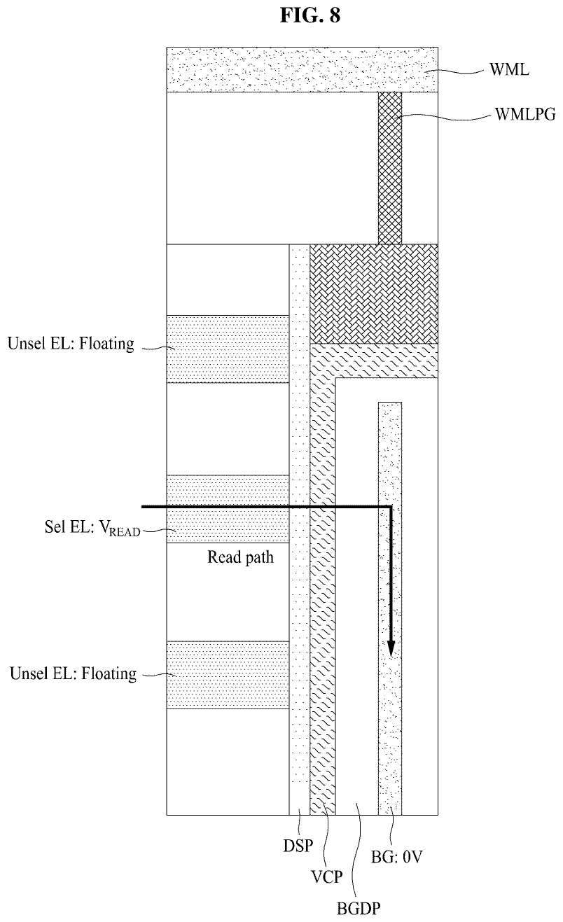

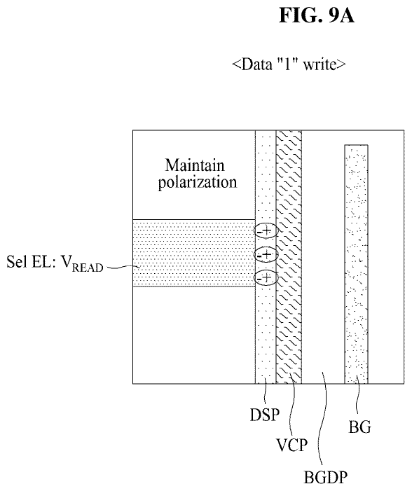

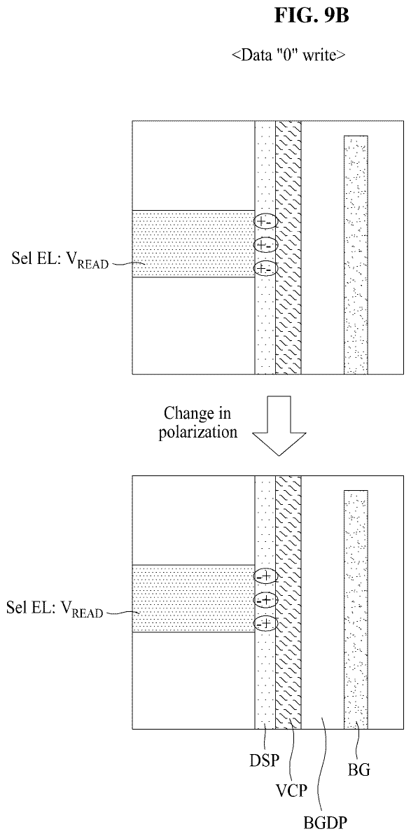

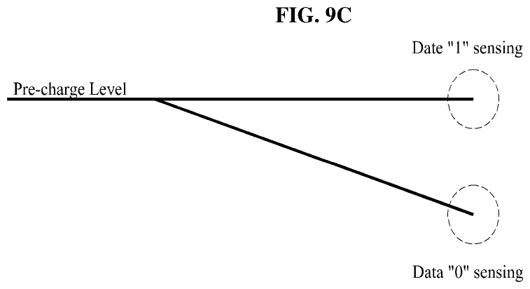

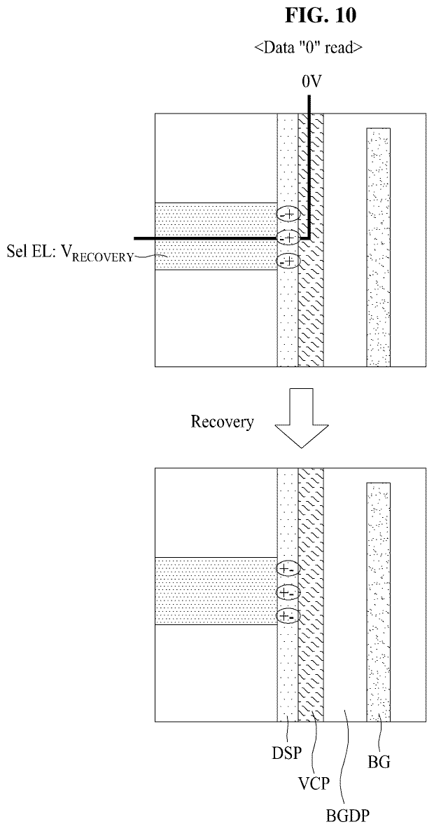

FIG. 7 is a flowchart showing a method of a read operation of a three-dimensional memory according to an embodiment, FIG. 8 is a diagram showing a structure of a three-dimensional memory to describe a method of a read operation of the three-dimensional memory according to an embodiment, FIGS. 9A to 9C are each a diagram for describing a method of a read operation of a three-dimensional memory according to an embodiment, and FIG. 10 is a diagram for describing a recovery operation performed after a method of a read operation of a three-dimensional memory is performed, according to an embodiment.

It is assumed that the reading operation method described below is performed by a three-dimensional memory having the structure described above with reference to FIGS. 1 to 3. Referring to FIG. 7, in step S710, the three-dimensional memory may apply a voltage along the read path (the read path from each of the gate electrodes EL1, EL2, EL3 toward each of the read metal lines RML0, RML1, RML2) between each of the gate electrodes EL1, EL2, EL3, and each of the read metal lines RML0, RML1, RML2.

For example, as shown in FIG. 8, the three-dimensional memory may apply a voltage along the read path (the read path composed of the selected gate electrode Sel EL, the data storage pattern DSP, the vertical channel pattern VCP in which the channel is formed, the back gate dielectric pattern BGDP, and the read wire) from the selected gate electrode EL toward the read wire by applying a positive read voltage VREAD to the selected gate electrode Sel EL corresponding to the target memory cell to be subjected to the read operation among the gate electrodes EL1, EL2, EL3, while applying a ground voltage 0V to the back gate BG of the selected vertical channel structure Sel VS including the target memory cell of the vertical channel structures VS to be subjected to a read operation, and floating the remaining gate electrodes Unsel EL.

At this time, the value of the read voltage VREAD may be determined to be a value greater than or equal to a sum of a turn-on voltage value and a sensing voltage value for causing the back gate dielectric pattern BGDP to be turned on to the switching element. In an example, when the turn-on voltage value is 2 V and the sensing voltage value is 1 V, the value of the read voltage may be determined to be a value of 3 V or more.

Accordingly, in step S720, the three-dimensional memory may read the polarization state of the data storage pattern DSP by the voltage applied along the read path. More specifically, the three-dimensional memory may read the polarization state of the data storage pattern DSP by determining, through direct voltage sensing, that the polarization states of the data storage patterns DSP are changed by the voltage applied along the read path.

For example, if data of “1” is written as a positive voltage is applied to the target memory cell region in the data storage pattern DSP and the polarization state of the target memory cell regions in the data storage patterns DSP is as shown in FIG. 9A, the polarization state of target memory cell regions may be continuously maintained regardless of the voltage being applied in step S710.

On the other hand, if data of “0” is written as a negative voltage is applied to the target memory cell region in the data storage pattern DSP so that the polarization state of the target memory cell regions in the data storage patterns DSP is as shown at the top of FIG. 9B, the polarization state of target memory cell regions may be changed as shown at the bottom of FIG. 9b in response to a positive voltage being applied in step S710.

Such a read operation method corresponds to a memory operation method of FRAM.

Based on the characteristics described in the examples, the three-dimensional memory senses voltages of different values from each other as shown in FIG. 9C according to the value of data written to the target memory cell region, in response to the voltage for reading being applied along the read path after the pre-charging level. Thus, the three-dimensional memory can read the value of the data written to the target memory cell region based on the directly sensed voltage value.

However, when the polarization state of the target memory cell region in the data storage pattern DSP is changed in response to the application of the voltage in step S710 because “0” data is written to the target memory cell regions in the data storage patterns DSP and the polarization state of each target memory cell region is as shown in the upper part of FIG. 9B, an operation of restoring the polarization state of a target memory cell region again is required.

Accordingly, when it is determined through voltage sensing that the polarization state of the data storage pattern DSP changes in the read operation, the three-dimensional memory may perform a recovery operation of recovering the polarization state of a data storage pattern DSP after the read operation, as illustrated in FIG. 10.

When the back gate dielectric pattern BGDP is interposed between the vertical channel pattern VCP and the back gate BG in the three-dimensional memory, the back gate dielectric patterns BGDP function as insulating films in response to the ground voltage 0V being applied to the back gates BG in steps S710 to S720, so that the read state of the data storage pattern DSP can be focused on reading.

FIGS. 11A to 11B are each a diagram for describing a role of a gate dielectric pattern in method of a write operation and method of a read operation of a three-dimensional memory according to an embodiment.

The back gate dielectric pattern BGDP interposed between the vertical channel pattern VCP and the back gate BG may play different roles in the write operation and the read operation. For example, the back gate dielectric pattern BGDP may precharge the vertical channel pattern VCP in response to the application of the pass voltage VPASS to the back gate BG in steps S410 to S420 described above, so that a channel is formed in the vertical channel pattern BCP and a polarization state is wrote in the data storage pattern DSP as illustrated in FIG. 11A.

For another example, the back gate dielectric pattern BGDP may function as a conductive state of the switching element as shown in FIG. 11B in response to the ground voltage 0V being applied to the back gate BG in steps S710 to S720 described above, thereby focusing on reading the read state of the data storage pattern DSP.

To this end, the back gate dielectric pattern BGDP may be formed of a material that 32 functions as a switching element that is turned on when a voltage (e.g., a pass voltage) of a specific value is applied, and functions as a switching device in a conductive state when a voltage less than the specific value is applied. In an example, the back gate dielectric pattern BGDP may be formed of at least one of a material having a dielectric constant of 4 or more, an oxide material, and a phase change material.

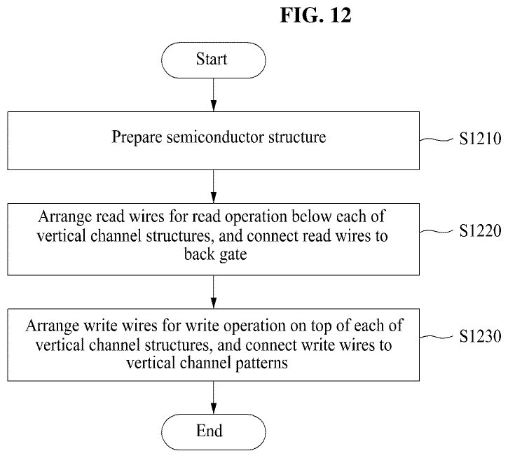

FIG. 12 is a flowchart showing a method of manufacturing a three-dimensional memory according to an embodiment.

The manufacturing method described below is for manufacturing a three-dimensional memory of the structure described above with reference to FIGS. 1 to 11, and is assumed to be performed by an automated and mechanized manufacturing system.

Referring to FIG. 12, in step S1210, the manufacturing system may prepare the semiconductor structure SEMI-STR. Here, the semiconductor structure SEM-STR may include gate electrodes EL1, EL2, EL3 that are vertically spaced and stacked while being formed to extend in a horizontal direction on the substrate SUB; and vertical channel structures VS that are formed to extend in the vertical direction while penetrating through the gate electrodes EL1 EL2 EL3. That is, the semiconductor structure SEMI-STR may include the stacked structures ST and the vertical channel structures VS having the structures described above with reference to FIGS. 1 to 3.

In step S1220, the manufacturing system may arrange the read metal lines RML0, RML1, RML2 for the read operation of the three-dimensional memory at the lower end of each of the vertical channel structures VS and connect the read wires to the back gate BG.

In step S1230, the manufacturing system may place the write metal lines WML0, WML1, WML2 for the write operation of the three-dimensional memory on top of each of the vertical channel structures VS and connect the write wires to the vertical channel pattern VCP.

At this time, the manufacturing system may place the write metal lines WML0, WML1, WML2 at positions symmetrical to each other with the read metal lines RML0, RML1, RML2 in the three-dimensional memory.

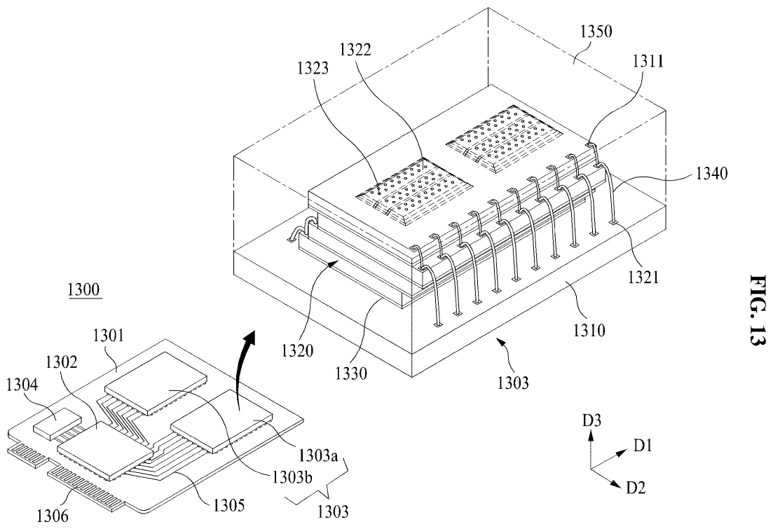

FIG. 13 is a perspective view schematically showing an electronic system including a three-dimensional memory according to one embodiment.

Referring to FIG. 13, an electronic system 1300 including a three-dimensional memory according to embodiments may include a main substrate 1301, a controller 1302 mounted on the main substrate 1301, one or more semiconductor packages 1303, and a DRAM 1304.

The semiconductor package 1303 and the DRAM 1304 may be connected to each other with the controller 1302 by wire patterns 1305 provided in the main substrate 1301.

The main substrate 1301 may include a connector 1306 including a plurality of pins coupled with an external host. The number and placement of the plurality of pins in the connector 1306 may vary depending on the communication interface between the electronic system 1300 and the external host.

The electronic system 1300 may communicate with an external host according to any one of interfaces such as Universal Serial Bus (USB), Peripheral Component Interconnect Express (PCIExpress), Serial Advanced Technology Attachment (SATA), and M-Phy for Universal Flash Storage (UFS), for example. The electronic system 1300 may be operated by, for example, a power source supplied from an external host via a connector 1306. The electronic system 1300 may further include a power management integrated circuit (PMIC) that distributes power supplied from an external host to the controller 1302 and the semiconductor package 1303.

The controller 1302 may write data to the semiconductor package 1303 or read data from the semiconductor package 1303, and may improve the operating speed of the electronic system 1300.

The DRAM 1304 may be a buffer memory for mitigating a speed difference between the semiconductor package 1303, which is a data storage space, and an external host. The DRAM 1304 included in the electronic system 1300 may also operate as a kind of cache memory and may provide space for temporarily storing data in control operations for the semiconductor package 1303. When the electronic system 1300 includes a DRAM 1304, the controller 1302 may further include a DRAM controller for controlling the DRAM 1304 in addition to a NAND controller for controlling the semiconductor package 1303.

The semiconductor package 1303 may include first and second semiconductor packages 1303a, 1203b spaced apart from each other. The first and second semiconductor packages 1303a, 1203b may each be a semiconductor package including a plurality of semiconductor chips 1320. Each of the first and second semiconductor packages 1303a, 1203b may include a package substrate 1310, semiconductor chips 1320 on the package substrate 1310; adhesive layers 1330 disposed on a bottom surface of each of the semiconductor chips 820; connection structures 1340 electrically connecting the semiconductor chips 1320 and the package substrate 1310); and a molding layer 1350 covering the semiconductor chips 1320) and the connection structures 1340 on the package substrate 1210.

The package substrate 1310 may be a printed circuit board including package top pads 1311. Each of the semiconductor chips 1320 may include input/output pads 1321. Each of the semiconductor chips 1320 may include the three-dimensional memory described above with reference to FIGS. 1-12. More specifically, each of the semiconductor chips 1320 may include gate stacked structures 1322 and memory channel structures 1323. The gate stacked structures 1322 may correspond to the above-described stacked structures ST, and the memory channel structures 1323 may correspond to at least one vertical connection pattern VP with the above-described vertical channel structures VS.

The connection structures 1340 may be, for example, bonding wires that electrically connect the input/output pads 1321 and the package top pads 1311. Thus, in each of the first and second semiconductor packages 1303a, 1203b, the semiconductor chips 1320 may be electrically connected to each other in a bonding wire manner, and may be electrically connected with the package top pads 1311 of the package substrate 1310. According to embodiments, in each of the first and second semiconductor packages 1303a, 1203b, the semiconductor chips 1320 may be electrically connected to each other by a through-electrode (through silicon via), instead of bonding wire-type connection structures 1340.

Unlike shown, the controller 1302 and the semiconductor chips 1320 may be included in one package. The controller 1302 and the semiconductor chips 1320 may be mounted on a separate interposer substrate different from the main substrate 1301, and the controller 1302 and semiconductor chips 1320 are connected to each other by wire provided in the interposer substrate.

### MODES FOR CARRYING OUT THE INVENTION

Although the above embodiments have been described by way of limited embodiments and drawings, various modifications and variations are possible from the above description to those skilled in the art. For example, suitable results may be achieved even if the described techniques are performed in a different order than the described method, and/or components of the described system, structure, apparatus, circuitry, etc. are combined or combined in a different form than the described method or replaced or substituted by other components or equivalents.

Therefore, other implementations, other embodiments, and equivalents to the claims also fall within the scope of the following claims.

1. A three-dimensional memory, comprising:
gate electrodes that are formed on a substrate to extend in the horizontal direction and are stacked and spaced apart from each other in the vertical direction;
vertical channel structures that pass through the gate electrodes and extend in the vertical direction, wherein each of the vertical channel structures comprises a data storage pattern, a vertical channel pattern, and a back gate;
write wires for a write operation of the three-dimensional memory, each of which is arranged on top of each of the vertical channel structures and connected to the vertical channel patterns; and
read wires for a read operation of the three-dimensional memory, each of which is arranged below each of the vertical channel structures and connected to the back gates.

2. The three-dimensional memory of claim 1, wherein
the write wires and the read wires are respectively arranged at positions symmetrical to each other within the three-dimensional memory.

3. The three-dimensional memory of claim 1, wherein
each of the vertical channel structures arranged in a same row or a same column among the vertical channel structures is connected to a different one of the write wires, and simultaneously is connected to a different one of the read wires.

4. The three-dimensional memory of claim 1, wherein
the three-dimensional memory performs the write operation of writing a polarization state of the data storage pattern along a write path between each of the gate electrodes and each of the write wires.

5. The three-dimensional memory of claim 1, wherein
the three-dimensional memory performs the read operation of reading a polarization state of the data storage pattern along a read path between each of the gate electrodes and each of the read wires.

6. The three-dimensional memory of claim 5, wherein
the three-dimensional memory determines, through voltage sensing, whether the polarization state of the data storage pattern is changed by a voltage applied along the read path between each of the gate electrodes and each of the read wires, thereby reading the polarization state of the data storage pattern.

7. The three-dimensional memory of claim 6, wherein
when it is determined through the voltage sensing that the polarization state of the data storage pattern is changed by the voltage applied along the read path between each of the gate electrodes and each of the read wires, the three-dimensional memory further performs a recovery operation of recovering the polarization state of the data storage pattern after the read operation.

8. The three-dimensional memory of claim 1, wherein
the three-dimensional memory has a source free structure in which a source region is omitted below each of the vertical channel structures.

9. The three-dimensional memory of claim 1, wherein
the three-dimensional memory performs the write operation on the target memory cell to be subjected to the write operation pre-charged in advance, and simultaneously pre-charges any one of the remaining vertical channel structures other than a selected vertical channel structure comprising the target memory cell among the vertical channel structures.

10. The three-dimensional memory of claim 1, wherein
each of the vertical channel structures further comprises a back gate dielectric pattern interposed between the vertical channel pattern and the back gate.

11. The three-dimensional memory of claim 10, wherein
the back gate dielectric pattern pre-charges the vertical channel pattern in response to a pass voltage being applied through the back gate during the write operation.

12. The three-dimensional memory of claim 10, wherein
the back gate dielectric pattern functions as a conductive state of a switching element in response to a ground voltage being applied through the back gate during the read operation, thereby focusing on reading the polarization state of the data storage pattern.

13. A method of a write operation of a three-dimensional memory comprising:
gate electrodes that are formed on a substrate to extend in the horizontal direction and are stacked and spaced apart from each other in the vertical direction; vertical channel structures that pass through the gate electrodes and extend in the vertical direction, wherein each of the vertical channel structures comprises a data storage pattern, a vertical channel pattern, and a back gate; write wires for a write operation, each of which is arranged on top of each of the vertical channel structures and connected to the vertical channel patterns; and read wires for a read operation, each of which is arranged below each of the vertical channel structures and connected to the back gates,
the method comprising:
applying a voltage along a write path between each of the gate electrodes and each of the write wires; and
writing a polarization state of the data storage pattern by the voltage applied along the write path.

14. The method of a write operation of a three-dimensional memory of claim 13, wherein
the writing further comprises:
performing the write operation on the target memory cell to be subjected to the write operation pre-charged in advance, and simultaneously pre-charging any one of the remaining vertical channel structures other than a selected vertical channel structure comprising the target memory cell among the vertical channel structures.

15. The method of a write operation of a three-dimensional memory of claim 13, wherein
a back gate dielectric pattern interposed between the vertical channel pattern and the back gate pre-charges the vertical channel pattern in response to a pass voltage being applied through the back gate in the write operation method.

16. A method of a read operation of a three-dimensional memory comprising:
gate electrodes that are formed on a substrate to extend in the horizontal direction and are stacked and spaced apart from each other in the vertical direction; vertical channel structures that pass through the gate electrodes and extend in the vertical direction, wherein each of the vertical channel structures comprises a data storage pattern, a vertical channel pattern, and a back gate; write wires for a write operation, each of which is arranged on top of each of the vertical channel structures and connected to the vertical channel patterns; and read wires for a read operation, each of which is arranged below each of the vertical channel structures and connected to the back gates,
the method comprising:
applying a voltage along a read path between each of the gate electrodes and each of the read wires; and
reading a polarization state of the data storage pattern by determining, through voltage sensing, whether the polarization state of the data storage pattern is changed by the voltage applied along the read path.

17. The method of a read operation of a three-dimensional memory of claim 16, wherein
when it is determined through the voltage sensing that the polarization state of the data storage pattern is changed by the voltage applied along the read path, the method of a read operation of a three-dimensional memory further comprises:
performing a recovery operation of recovering the polarization state of the data storage pattern after the reading.

18. The method of a read operation of a three-dimensional memory of claim 16, wherein
a back gate dielectric pattern interposed between the vertical channel pattern and the back gate functions as a conductive state of a switching element in response to a ground voltage being applied through the back gate in the method of a read operation, thereby focusing on reading the polarization state of the data storage pattern.

19. A method for manufacturing a three-dimensional memory, comprising:
preparing a semiconductor structure comprising: gate electrodes that are formed on a substrate to extend in the horizontal direction and are stacked and spaced apart from each other in the vertical direction; and vertical channel structures that pass through the gate electrodes and extend in the vertical direction, wherein each of the vertical channel structures comprises a data storage pattern, a vertical channel pattern, and a back gate;
arranging read wires for a read operation of the three-dimensional memory below each of the vertical channel structures, and connecting the read wires to the back gate; and arranging write wires for a write operation of the three-dimensional memory on top of each of the vertical channel structures, and connecting the write wires to the vertical channel patterns.

20. The method for manufacturing a three-dimensional memory of claim 19, wherein
the arranging the write wires on top of each of the vertical channel structures, and connecting the write wires to the vertical channel patterns comprises:
arranging the write wires at positions symmetrical to the read wires within the three-dimensional memory.
